(19) United States
(12) Patent Application Publication
(10) Pub. No.: US 2014/0306234 A1
(43) Pub. Date: Oct. 16, 2014

(54) LIGHT EMITTING DEVICE

(71) Applicant: DISCO CORPORATION, TOKYO (JP)

(72) Inventor: Minoru Suzuki, Tokyo (JP)

(73) Assignee: DISCO CORPORATION, TOKYO (JP)

(21) Appl. No.: 14/252,445

(22) Filed: Apr. 14, 2014

(30) Foreign Application Priority Data
Apr. 16, 2013 (JP) 2013-085733

(51) Int. Cl. H01L 33/32

(52) U.S. Cl. CPC H01L 33/32
USPC 257/76

(57) ABSTRACT

A light emitting device includes a light emitting diode whose front surface is supported and fixed on a package mounting surface and a transparent member bonded to the back surface of the light emitting diode. The light emitting diode has a light emitting layer on the front surface side.

### BACKGROUND OF THE INVENTION

1. Field of the Invention

The present invention relates to a light emitting device formed with a light emitting diode having a light emitting layer.

2. Description of the Related Art

Light emitting devices including light emitting diode (LED), laser diode (LD), and so forth have been put into practical use. Normally these light emitting devices include a light emitting chip in which a light emitting layer that emits light by application of a voltage is formed. In manufacturing of the light emitting chip, first an epitaxial layer (crystal layer) is grown as the light emitting layer in the respective regions partitioned by planned dividing lines in a lattice manner on a substrate for crystal growth. Thereafter, the substrate for crystal growth is divided along the planned dividing lines to be turned to individual pieces. Therefore, the individual light emitting chips are formed.

In the light emitting chip in which the light emitting layer that emits green or blue light is an InGaN-based material layer, generally sapphire is used as the substrate for crystal growth and an n-type GaN semiconductor layer, an InGaN light emitting layer, and a p-type GaN semiconductor layer are sequentially epitaxially grown over this sapphire substrate. Furthermore, an external lead-out electrode is formed for each of the n-type GaN semiconductor layer and the p-type GaN semiconductor layer. The light emitting device having such a light emitting chip is required to provide higher luminance and various methods for enhancing the light extraction efficiency have been proposed (refer to e.g. Japanese Patent Laid-open No. Hei 4-10670).

### SUMMARY OF THE INVENTION

It is considered that the light emission efficiency of a light emitting device in which an LED or the like is mounted is higher by several percentages in the case of flip-chip mounting than in the case of wire-bonding mounting. In the flip-chip mounting, the front surface side (light emitting layer side) of the light emitting chip is fixed to the package mounting surface and the back surface side (sapphire substrate side) of the light emitting chip is exposed. Therefore, light generated in the light emitting layer by voltage application is transmitted through the sapphire substrate to be emitted from the back surface side (sapphire substrate side) of the light emitting chip. However, the back surface of this light emitting chip is the interface part between the sapphire substrate and an air layer and thus part of the light generated in the light emitting layer is reflected at this interface. The reflected light travels in the sapphire substrate to return to the light emitting layer and be absorbed. This absorbed light cannot be extracted to the external, which causes the lowering of the luminance. As above, there is a problem that the light extraction efficiency of the light emitting diode decreases when the ratio of light reflected by the sapphire substrate to be absorbed by the light emitting layer becomes higher.

Therefore, an object of the present invention is to provide a light emitting device that allows further enhancement in the light extraction efficiency in a light emitting diode mounted by flip-chip mounting.

In accordance with an aspect of the present invention, there is provided a light emitting device including a package having a bottom surface and an inner circumferential surface and a light emitting diode having a substrate and a light emitting layer formed on a front surface of the substrate. The side of the light emitting layer is mounted on the bottom surface of the package. The light emitting device further includes a transparent member bonded to a back surface of the substrate of the light emitting diode.

According to this configuration, the transparent member is bonded to the back surface of the light emitting diode. Thus, in light output from the light emitting layer, light reflected at the back surface of the light emitting diode can be decreased and light transmitted to the transparent member side can be increased. Furthermore, the ratio of light that returns to the light emitting layer in light reflected at the interface between the transparent member and an air layer can be suppressed to a low ratio according to the thickness of the transparent member. As a result, an effect of improvement in the light extraction efficiency is provided.

Preferably, the light emitting diode is formed by stacking the light emitting layer formed of a GaN semiconductor layer over a sapphire substrate or a GaN substrate. According to this configuration, the light extraction efficiency can be enhanced in the light emitting diode that emits blue or green light. Furthermore, because the light emitting diode including the sapphire substrate or GaN substrate is formed, the light reflected at the interface between the transparent member and the air layer can be output from the substrate side surface. This also can enhance the light extraction efficiency. In addition, even when the sapphire substrate or GaN substrate is set thin, the reflected light can be made incident on a position outside the light emitting layer according to the thickness of the transparent member. Therefore, the thin sapphire substrate or GaN substrate can be utilized without the lowering of the light extraction efficiency, which can keep favorable processability provided by the thin substrate for crystal growth.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically showing a configuration example of a light emitting device according to an embodiment of the present invention;

FIG. 2 is a schematic sectional view showing how light is emitted in the light emitting device according to the embodiment of the present invention; and

FIG. 3 is a schematic sectional view showing how light is emitted in a light emitting device according to a comparative example.

### DETAILED DESCRIPTION OF THE PREFERRED EMBODIMENTS

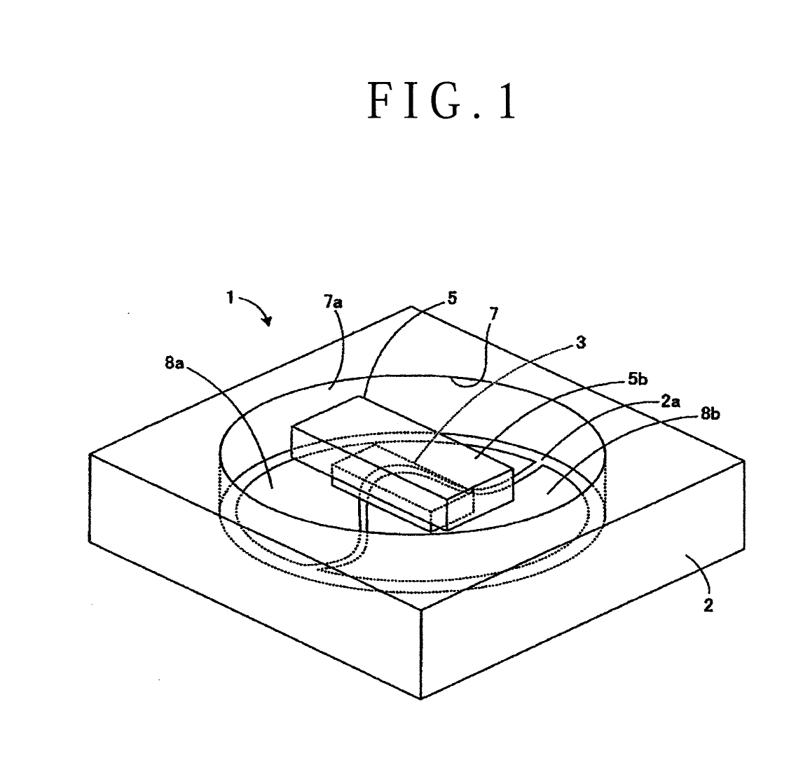

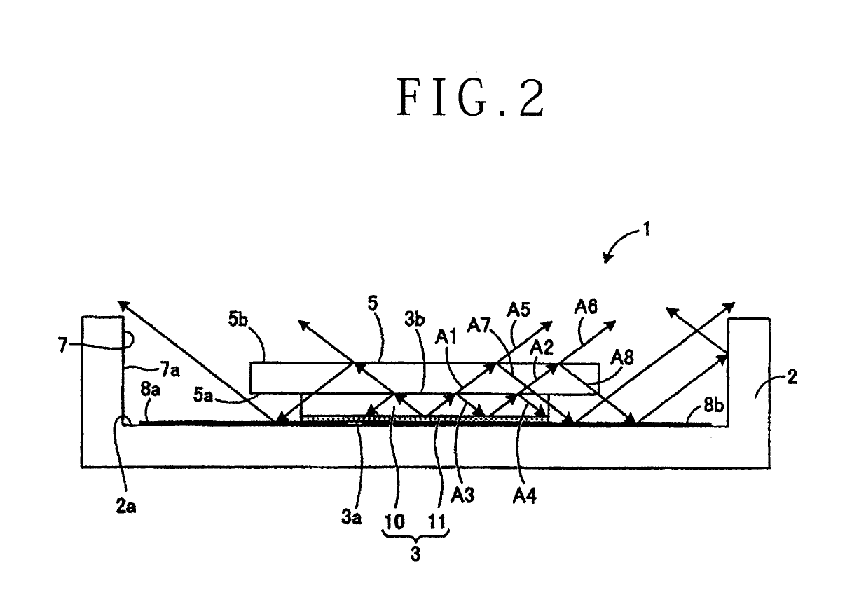

An embodiment of the present invention will be described below with reference to the accompanying drawings. FIG. 1 is a perspective view schematically showing a configuration example of a light emitting device according to the present embodiment. FIG. 2 is a schematic sectional view showing how light is emitted in the light emitting device according to the present embodiment. As shown in FIGS. 1 and 2, a light emitting device 1 includes a package 2, a light emitting diode 3 supported and fixed on a mounting surface 2a of the package 2, and a chip 5 bonded to this light emitting diode 3.

The package 2 is formed into a bottomed container shape having a recess 7 in which the light emitting diode 3 can be housed. The bottom surface of the recess 7 is used as the mounting surface 2a on which the light emitting diode 3 is mounted. On the mounting surface 2a, two connection electrodes 8a and 8b insulated from each other are disposed at a predetermined interval. The connection electrodes 8a and 8b are connected to an external power supply (not shown) via wiring (not shown) and so forth. The surfaces of the connection electrodes 8a and 8b act also as a reflective surface for light emitted from the light emitting diode 3. An inner circumferential surface 7a of the tubular shape of the recess 7 is subjected to processing for light reflection with high efficiency, such as mirror surface finishing.

The light emitting diode 3 includes a sapphire substrate 10 having a rectangular shape as its planar shape and a light emitting layer 11 formed on one major surface of the sapphire substrate 10 (lower surface in FIG. 2). The light emitting layer 11 includes plural semiconductor layers (GaN semiconductor layers) formed by using GaN-based semiconductor materials. In the light emitting diode 3, the fixed surface of the light emitting layer 11 supported and fixed on the mounting surface 2a (lower surface in FIG. 2) is defined as a front surface 3a and the surface of the sapphire substrate 10 bonded to the chip 5 (upper surface in FIG. 2) is defined as a back surface 3b.

The light emitting layer 11 is formed by sequentially epitaxially growing an n-type semiconductor layer (e.g. n-type GaN layer), in which electrons serve as the majority carriers, a semiconductor layer that emits light (e.g. InGaN layer), and a p-type semiconductor layer (e.g. p-type GaN layer), in which holes serve as the majority carriers. On the front surface 3a of the light emitting diode 3, electrodes (not shown) connected to the n-type semiconductor layer and the p-type semiconductor layer, respectively, are provided. These electrodes are each formed by a protrusion-shaped terminal called a bump. They are connected to the connection electrodes 8a and 8b through the supporting and fixing of the front surface 3a of the light emitting diode 3 on the mounting surface 2a, so that the light emitting diode 3 is mounted by flip-chip mounting.

The chip 5 is bonded to the back surface 3b of the light emitting diode 3 (sapphire substrate 10). The chip 5 is formed of a transparent member of glass (e.g. soda glass or borosilicate glass), resin, etc. and is formed by a material through which light radiated from the light emitting layer 11 is transmitted. The chip 5 has a first major surface 5a bonded to the sapphire substrate 10 and a second major surface 5b formed on the opposite side to this first major surface 5a. The respective areas of the first major surface 5a and the second major surface 5b of the chip 5 are larger than the area of the back surface 3b of the light emitting diode 3 and the luminance of the light emitting device 1 can be improved at a higher degree when the areas of the first and second major surfaces 5a and 5b are larger as described later. Furthermore, it is preferable for the chip 5 to have a thickness equivalent to or larger than that of the sapphire substrate 10 and the luminance of the light emitting device 1 can be improved at a higher degree when the thickness of the chip 5 is larger as described later. The first major surface 5a of the chip 5 is bonded to the back surface 3b of the light emitting diode 3 by a resin (not shown) having transparency.

When a voltage from the power supply connected to the wiring (not shown) and so forth of the package 2 is applied to the light emitting layer 11 of the light emitting diode 3, electrons flow from the n-type semiconductor layer into the semiconductor layer of the light emitting layer 11 and holes flow from the p-type semiconductor layer into it. As a result, the recombination of the electrons and the holes occurs in the semiconductor layer that emits light and light having a predetermined wavelength is emitted. In the present embodiment, because the semiconductor layer that emits light is formed by using a GaN-based semiconductor material, blue or green light corresponding to the band gap of the GaN-based semiconductor material is emitted.

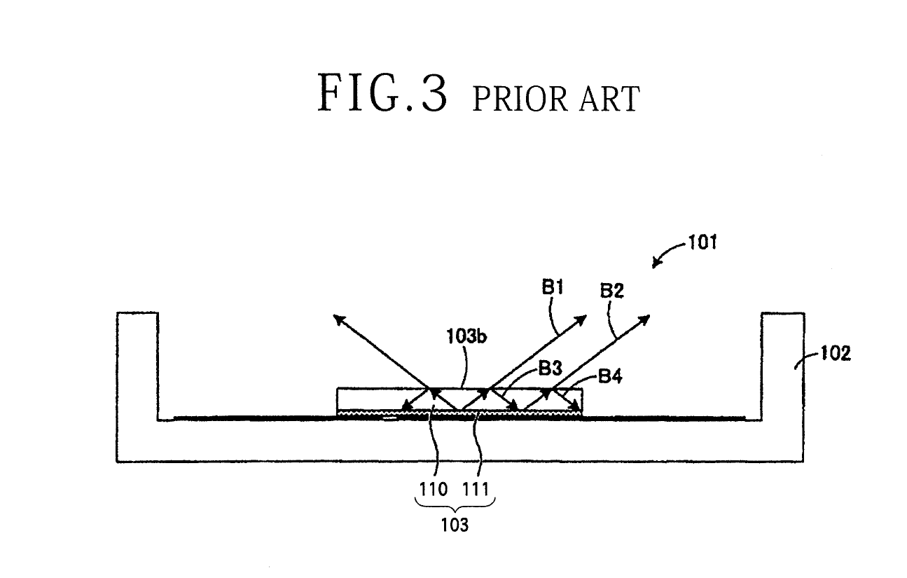

Next, a luminance improvement effect by the light emitting device 1 according to the present embodiment will be described with reference to a light emitting device according to a comparative example. FIG. 3 is a schematic sectional view of the light emitting device according to the comparative example and shows how light is emitted from a light emitting diode. As shown in FIG. 3, a light emitting device 101 according to the comparative example has a configuration common to the light emitting device 1 according to the present embodiment except for the chip 5. Specifically, the light emitting device 101 includes a package 102 and a light emitting diode 103 supposed and fixed on this package 102 and the light emitting diode 103 includes a sapphire substrate 110 and a light emitting layer 111.

First, luminance realized in the light emitting device 101 according to the comparative example will be described. Light generated in the light emitting layer 111 of the light emitting device 101 according to the comparative example is incident on the interface between the sapphire substrate 110 and an air layer, which is equivalent to a back surface 103b of the light emitting diode 103. Part of the light is transmitted to the air layer side to be emitted (e.g. optical paths B1 and B2) and the remaining part thereof is reflected (e.g. optical paths B3 and B4). The light reflected at the back surface 103b (sapphire substrate 110) of the light emitting diode 103 to travel on the optical paths B3 and B4 is incident on the forming region of the light emitting layer 111 and thus is absorbed by the light emitting layer 111, which causes the lowering of the luminance. In the light emitting device 101 according to the comparative example, the reflective surface for the light generated in the light emitting layer 111 is the back surface 103b of the light emitting diode 103 in contact with the air layer. Therefore, the ratio of the light reflected at this back surface 103b (optical paths B3 and B4) is higher compared with in the configuration in which the chip 5 is bonded to the back surface 3b of the light emitting diode 3 like the light emitting device 1 according to the present embodiment. Part of the light reflected at the back surface 103b of the light emitting diode 103 is output from the side surface of the sapphire substrate 110. However, when the thickness of the sapphire substrate 110 becomes smaller, the distance between the light emitting layer 111 and the back surface 103b of the light emitting diode 103 becomes shorter and the ratio of light reflected at this back surface 103b to return to the light emitting layer 111 becomes higher. Therefore, the light extraction efficiency decreases.

On the other hand, as shown in FIG. 2, in the light emitting device 1 according to the present embodiment, light generated in the light emitting layer 11 is incident on the back surface 3b of the light emitting diode 3 as the interface between the sapphire substrate 10 and the chip 5. Part of the light is transmitted to the side of the chip 5 (e.g. optical paths A1 and A2) and the remaining part thereof is reflected (e.g. optical paths A3 and A4). Furthermore, the light transmitted to the side of the chip 5 is incident on the second major surface 5b of the chip 5 as the interface between the chip 5 and an air layer. Part of the light is transmitted to the air layer side to be emitted (e.g. optical paths A5 and A6) and the remaining part thereof is reflected (e.g. optical paths A7 and A8).

In the light emitting device 1 according to the present embodiment, the chip 5 formed of the transparent member is bonded to the back surface 3b of the light emitting diode 3, which serves as the first reflective surface for the light generated in the light emitting layer 11. Therefore, the ratio of the light reflected at the back surface 3b of this light emitting diode 3 (optical paths A3 and A4) can be suppressed to a lower ratio compared with in a configuration in which the back surface 3b of the light emitting diode 3 is in direct contact with the air layer (comparative example). This is because the refractive index of the chip 5 formed of the transparent member is closer to that of the sapphire substrate 10 than that of the air. Therefore, the light emitting device 1 of the present embodiment allows transmission of more light to the side of the chip 5 at the back surface 3b of the light emitting diode 3 compared with the comparative example and allows reduction in the amount of light reflected at the back surface 3b of the light emitting diode 3 to be absorbed by the light emitting layer 11. As a result, the light emitting device 1 can decrease the amount of light that is reflected at the back surface 3b of the light emitting diode 3 and travels on the optical paths A3 and A4 to return to the light emitting layer 11 and be absorbed and thus can improve the light extraction efficiency.

Furthermore, the chip 5 formed of the transparent member bonded to the back surface 3b of the light emitting diode 3 has a required thickness. Thus, in light reflected at the second major surface 5b of the chip 5, e.g. light traveling on the optical paths A7 and A8 is incident on the bottom surface of the recess 7 (connection electrodes 8a and 8b and mounting surface 2a) outside the forming region of the light emitting layer 11. The light incident on the connection electrodes 8a and 8b and the mounting surface 2a outside the forming region of the light emitting layer 11 is reflected to the inner circumferential surface 7a of the recess 7. The light traveling on the optical path A7 is output from the side surface of the sapphire substrate 10 and reflected by the connection electrodes 8a and 8b and the inner circumferential surface 7a of the recess 7 to be extracted to the external. The light traveling on the optical path A8 is reflected by the connection electrodes 8a and 8b and the inner circumferential surface 7a of the recess 7 to be extracted to the external, without passing through the sapphire substrate 10. Therefore, in the light reflected at the second major surface 5b of the chip 5, the light reflected to the outside of the forming region of the light emitting layer 11 can be extracted without being absorbed by the light emitting layer 11.

As just described, according to the light emitting device 1 in accordance with the present embodiment, due to the bonding of the chip 5 formed of the transparent member to the back surface 3b of the light emitting diode 3, the distance from the light emitting layer 11 to the second major surface 5b of the chip 5, which serves as a reflection position, becomes longer. This can suppress the ratio of light that returns to the forming region of the light emitting layer 11 to a low ratio and enhance the light extraction efficiency compared with the case in which light is reflected at the back surface 103b of the light emitting diode 103 like in the comparative example.

As described above, according to the light emitting device 1 in accordance with the present embodiment, the chip 5 formed of the transparent member is provided on the back surface 3b of the light emitting diode 3. Thus, the amount of light reflected at the back surface 3b of the light emitting diode 3 to return to the light emitting layer 11 can be reduced compared with the comparative example. Moreover, the ratio of light that returns to the light emitting layer 11 in the light reflected at the second major surface 5b of the chip 5 can be suppressed to a low ratio. Thus, the light extraction efficiency can be enhanced and improvement in the luminance can be achieved.

Because the sapphire substrate is hard and is not easy to process, it is preferable to use a thin sapphire substrate to enhance the processability. In this case, in the light emitting device 101 of the comparative example, the distance between the light emitting layer 111 and the back surface 103b of the light emitting diode 103 (upper surface of the sapphire substrate 110 in FIG. 3) is shortened and the ratio of light reflected at this back surface 103b to return to the light emitting layer 111 becomes higher. Thus, the light extraction efficiency is lowered. In contrast, in the light emitting device 1 according to the present embodiment, the light extraction efficiency can be kept high by the chip 5 even when the thickness of the sapphire substrate 10 is reduced. That is, there is no need to increase the thickness of the sapphire substrate 10 for keeping the light extraction efficiency to sacrifice the processability.

Next, an experiment made for confirming the luminance improvement effect of the light emitting device 1 according to the present embodiment will be described. In this experiment, the following samples were fabricated: three kinds of light emitting devices 1 (working examples 1 to 3) that each had a configuration similar to that of the light emitting device 1 according to the present embodiment and were different from each other in the size (thickness and/or area) of the chip 5 formed of a transparent member and a light emitting device (comparative example) that did not have the chip 5 similarly to the comparative example.

The light emitting diode 3 having the same specifications was used in all of working examples 1 to 3 and the comparative example. Specifically, as the light emitting diode 3, one was employed that was obtained by forming the light emitting layer 11 formed of a GaN semiconductor layer over the sapphire substrate 10 that had an area of 0.595 mm×0.270 mm as the area of the front surface and back surface (vertical×horizontal) and had a thickness (height) of 0.15 mm. Bonding between the sapphire substrate 10 and the chip 5 was made by using an adhesive made of a resin having sufficiently low absorbance.

For the chip 5 used in working examples 1 to 3, soda glass was used as the transparent member. The chip 5 used in working example 1 was formed to have an area of 0.7 mm×0.3 mm as the area of the front surface and back surface (vertical×horizontal) and have a thickness (height) of 0.15 mm. The chip 5 used in working example 2 was formed to have an area of 0.7 mm×0.9 mm as the area of the front surface and back surface and have a thickness of 0.15 mm. The chip 5 used in working example 3 was formed to have an area of 0.7 mm×0.9 mm as the area of the front surface and back surface and have a thickness of 0.5 mm. In this experiment, the total value of the intensity (power) of all light radiated from each light emitting device 1 was measured (total radiant flux measurement) and converted into the luminance calculated with the comparative example using no chip 5 regarded as the criterion (100%). The measurement result (luminance) was 109.2%, 111.5%, and 118.0% in working examples 1, 2, and 3, respectively.

As can be understood from the measurement result, providing the chip 5 on the back surface side of the light emitting diode 3 can enhance the light extraction efficiency. Furthermore, a tendency could be confirmed that a larger area of the first major surface 5a and the second major surface 5b of the chip 5 provided higher luminance of the light emitting device 1 and a larger thickness of the chip 5 provided higher luminance of the light emitting device 1. Because it was confirmed that the luminance increased to a higher level when the thickness and area of the chip 5 were larger, it is preferable for the chip 5 to be formed with large area and/or thickness within such a range as not to affect the flip-chip mounting.

The present invention is not limited to the above embodiment and can be carried out with various changes. In the above embodiment, the sizes, shapes, and so forth of the respective constituent elements are not limited to those represented in the accompanying drawings and can be appropriately changed within such a range as to exert the effects of the present invention. Other elements can be carried out with appropriate changes without departing from the scope of the object of the present invention.

For example, although the light emitting diode 3 using a sapphire substrate and a GaN-based semiconductor material is exemplified in the above embodiment, the substrate for crystal growth and the semiconductor material are not limited to the embodiment. For example, a GaN substrate may be used as the substrate for crystal growth. Although it is preferable to reduce the thickness of the substrate for crystal growth, such as a sapphire substrate, to enhance the processability, the substrate for crystal growth does not necessarily need to be thin.

Furthermore, although the light emitting layer 11 in which an n-type semiconductor layer, a semiconductor layer that emits light, and a p-type semiconductor layer are sequentially provided is exemplified in the above embodiment, the configuration of the light emitting layer 11 is not limited thereto. It is enough for the light emitting layer 11 to be so configured as to be capable of at least emission of light through the recombination of electrons and holes. Furthermore, fine concavity and convexity may be formed in at least a partial region of the second major surface 5b of the chip 5 or processing of roughening the second major surface 5b to make it pearskin finished may be executed. This also can improve the luminance.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A light emitting device comprising:
a package having a bottom surface and an inner circumferential surface;
a light emitting diode having a substrate and a light emitting layer formed on a front surface of the substrate, a side of the light emitting layer being mounted on the bottom surface of the package; and
a transparent member bonded to a back surface of the substrate of the light emitting diode.

2. The light emitting device according to claim 1, wherein
the substrate is formed of a sapphire substrate or a GaN substrate and the light emitting layer is formed of a GaN semiconductor layer.

3. The light emitting device according to claim 1, wherein
area of a major surface of the transparent member is larger than area of the front surface and the back surface of the light emitting diode.

4. The light emitting device according to claim 1, wherein
a pair of electrodes having a reflection function are formed on the bottom surface of the package.

5. The light emitting device according to claim 5, wherein
the inner circumferential surface of the package is subjected to mirror surface processing.
